(19) United States
(12) Patent Application Publication
(10) Pub. No.: US 2006/0035413 A1
(43) Pub. Date: Feb. 16, 2006

(54) Thermal protection for electronic components during processing

(75) Inventors: Alan Rae, Hopkinton, MA (US); Bawa Singh, Voorhees, NJ (US)

Correspondence Address: LOWRIE, LANDO & ANASTASI, RIVERFRONT OFFICE, ONE MAIN STREET, ELEVENTH FLOOR, CAMBRIDGE, MA, 02142, US

(73) Assignee: Cookson Electronics, Inc.

(21) Appl. No.: 10/755,944

(22) Filed: Jan. 13, 2004

(51) Int. Cl. H01L 21/50

(52) U.S. Cl. 438/122; 165/185

(57) ABSTRACT

A method and device for cooling an electronic component during its manufacture, repair, or rework. There is a cooling unit in thermal communication with the electronic component which extracts heat therefrom.

### FIELD OF THE INVENTION

The present invention relates generally to a method and device for protecting heat sensitive features of electronic components from damage at typical processing temperatures.

### BACKGROUND OF THE INVENTION

As electronic products continue to shrink, there is a persistent effort to reduce the size of the integrated circuits (IC) found therein. At reduced architectural dimensions, an IC's heat sensitivity increases because of small feature size and thin wafers that distort easily. Additionally, ICs are now being designed to utilize novel and very thin organic or inorganic dielectrics, which also have limited thermal stability, in some cases well below 200° C. At the same time, the change to lead-free solders in ICs has increased the peak processing temperatures from, for example, about 220° C. for tin-lead solders to 245° C. or even 260° C. for tin-silver-copper solders.

The problem of thermal sensitivity is most pronounced with processor chips, which develop considerable heat during normal operation. In one current practice, these chips are mounted within an IC package using a flip chip format. During high power operation, the heat generated by the flip chip IC is dissipated through the package's solder joints to the main circuit board as well as through the package's lid.

In addition to ICs, other electronic components such as optoelectronic communication devices (e.g., transceivers) and displays (e.g., vacuum fluorescent displays) suffer from similar heat sensitivity during various processing stages. Specifically, optoelectronic communication devices are currently considered stable up to temperatures of about 80° C. to 90° C., while vacuum fluorescent displays must be assembled using selective soldering techniques because of their thermal instability. As with ICs, some method of heat dissipation is required to maintain the integrity of these electronic components during processing and in-service use.

Thermal dissipation devices are commonly used to keep electronic components stable during high temperature, in-service operation. These devices are in thermal communication with the component and generally employ conduction, convection, or a combination thereof to dissipate heat energy. Heat sinks in particular are common thermal dissipation devices for in-service operation. A heat sink is typically a mass of material that is thermally coupled to one of the electronic component's heat-conducting features, e.g., the package lid of an IC, with thermal grease or adhesive. Heat sinks rely on conduction to draw heat energy away from a high-temperature region toward the heat sink. The heat energy is then dissipated from the heat sink's surface to the atmosphere by convection.

A heat sink's thermal efficiency can be increased by forcing convection with an air stream over the surface, usually with a fan, or, in more advanced applications, by using a liquid to absorb heat from the heat sink. However, the efficiency of a heat sink is necessarily limited by the surface area of the heat sink, i.e., its convecting surface area. Further, while heat sinks have been utilized to dissipate heat during in-service operation, they have not been employed to address heat dissipation needs during elevated processing temperatures.

Reflective heat shields in the form of a metal cap or fiberboard masks have been used to try to protect electronic components during processing. However, these devices act only to shield the covered area from receiving the full impact of the ambient heat, rather than actually acting to help extract heat from the electronic component. As one consequence, these devices provide no protection to infrared heat. If there existed a method of extracting thermal energy from the electronic component during elevated temperature processing stages, the stability of heat sensitive components would accordingly be increased.

### SUMMARY OF THE INVENTION

Among the several aspects of the invention is to provide a method and device for cooling electronic components during processing so as to protect the thermally sensitive features thereof.

Briefly, therefore, the invention is directed to a method for cooling an electronic component during an elevated temperature operation during manufacture, repair, or rework thereof comprising bringing a temporary cooling unit into thermal communication with the electronic component, subjecting the electronic component to the elevated temperature operation during which the temporary cooling unit cools the electronic component, and removing the temporary cooling unit from thermal communication with the electronic component.

The invention is also directed to a method for cooling an electronic component during an elevated temperature operation during manufacture, repair, or rework thereof comprising bringing a cooling unit into thermal communication with the electronic component, subjecting the electronic component to the elevated temperature operation during which the cooling unit cools the electronic component by way of an endothermic reaction within the cooling unit.

The invention is further directed to a cooling unit to extract heat from an electrical component during exposure of the component to a process temperature between 100° C. and 300° C. during manufacture, repair, or reflow of the electrical component, the cooling unit comprising a cooling unit body and a cooling medium within the cooling unit body, wherein the cooling medium undergoes an endothermic reaction at the process temperature.

Other aspects and features of the invention will be in part apparent, and in part described hereafter.

### BRIEF DESCRIPTION OF THE DRAWINGS

FIG. 1 is a schematic illustration of a typical flip chip package prior to reflow processing.

FIG. 2 is a schematic illustration of a typical flip chip package with a cooling unit placed on the package's lid.

FIG. 3 is a schematic illustration of a flip chip package with a heat sink attached to the lid.

FIGS. 4a-4f are graphs of data for Example 1, representing the data collected by T1 and T2 during reflow at a peak temperature of 125° C.

FIGS. 5a-5f are graphs of data for Example 2, representing the data collected by T1 and T2 during reflow at a peak temperature of 220° C.

FIGS. 6a-6f are graphs of data for Example 3, representing the data collected by T1 and T2 during reflow at a peak temperature of 260° C.

Corresponding reference characters indicate corresponding parts throughout the drawings.

### DESCRIPTION OF THE PREFERRED EMBODIMENT(S)

The invention involves the cooling of electronic components during processing. While the invention can be used to dissipate heat throughout various elevated temperature operations, some package processing stages where heat sensitivity is particularly at issue include the reflow stage, the preheating stage prior to wave soldering, and any required rework or repair stage. A reflow process will be used herein for illustrative purposes. While the invention has potential application to myriad types of electronic components that are exposed to elevated processing temperatures, such as packaged ICs, multi-chip modules, optoelectronic communication devices, or electronic displays, a flip chip IC package will be used herein for illustrative purposes.

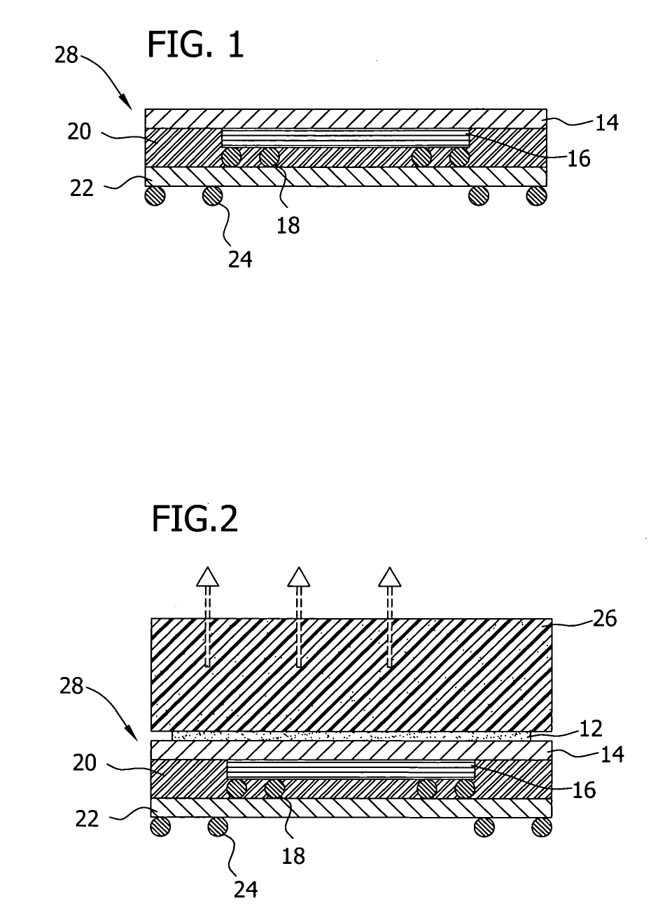

With reference to FIG. 1, a flip chip package 28 comprises a substrate 22 with a chip bonding area for mounting a semiconductor chip 16 thereon and a semiconductor chip with two sides, one side with electrically active features and a plurality of contact areas, and the other side without any electrical features. The semiconductor chip 16 is oriented such that the electrically active side faces toward the substrate 22, to which it is electrically connected by a plurality of solder bumps 18. The substrate 22 contains electrical traces, such as barrels or vias, that facilitate electrical connection between the semiconductor chip 16 and the device to which the package is ultimately attached by solder balls 24. Underfill material and molding compound, collectively 20, are applied to the substrate's chip side to provide lateral and subjacent support to the semiconductor chip 16. A lid 14 is then placed on the non-active side of the chip, such that the lid 14 adjoins both the chip 16 and the molding compound 20.

After the lid 14 is attached to the assembly, the package may be placed on another electronic component, such as a printed circuit board (PCB), which is used herein for illustrative purposes only. After the package's assembly, it will undergo subsequent processing stages at elevated temperatures. In accordance with this invention, heat is extracted from the electronic package during these processing stages prior to in-service use of, for example, the PCB.

Specifically, this invention relies on an endothermic reaction or process taking place in proximity to the electronic package to extract the internal heat thereof for the period between the package's assembly and its in-service operation, or for a segment thereof. In the preferred embodiment of the invention and with reference to the schematic illustration in FIG. 2, a cooling unit 26 is attached to the lid 14. A cooling unit is a structure specifically designed to be in thermal communication with the electronic package, thereby extracting and dissipating heat from the electronic package during processing stages with primary assistance from a cooling medium. Bringing the cooling unit into thermal communication with the electronic component encompasses positioning the unit in sufficient proximity to the component to allow significant transfer of heat from the component to the cooling unit. This typically involves placement of the cooling unit on the component.

While the cooling unit body provides some measure of heat extraction based on conduction, the endothermic reaction or process taking place within the cooling unit body at typical processing temperatures assists in cooling the electronic component. The invention can rely on the cooling medium undergoing any endothermic process such as a phase change, e.g., melting, vaporizing, or sublimation, or any endothermic reaction. The temperature at which the cooling medium undergoes its endothermic phase change or reaction under standard conditions may be moderately below the process temperature, provided conditions under which the component is subjected to the elevated temperature operation are such that the cooling medium still has capacity to extract heat at the process temperature. For example, water, which has a vaporization temperature of 100° C., can be used for cooling during a 150° C. operation, provided the operation is brought up to 150° C. quickly enough that all the water in the cooling unit does not evaporate prior to reaching the process temperature of 150° C. In the particular embodiments below, vaporization of a volatile species is used for illustrative purposes.

In one embodiment, the cooling unit is a structure made of an inorganic material. In this embodiment, two representative inorganic materials are hydrated CaSO₄ (Plaster of Paris) and reticulated zirconia foam (RZF), which is available commercially from Vesuvius Hi-Tech, Inc. of Alfred Station, New York. In the embodiment employing CaSO₄ as the inorganic material, the cooling unit is formed to shape and solidified in a room temperature casting process. The CaSO₄ is mixed with additives, per the supplier's instructions, and approximately 50 wt % water prior to casting. Desired dimensions can be achieved either through casting in molds or sawing single units from a larger bulk cast. As the CaSO₄ casting process is a room temperature process, organic materials are acceptable as the mold material. In the embodiment employing RZF as the inorganic material, the cooling unit is formed via a high temperature ceramic forming process akin to investment casting. An open-cell organic foam is impregnated with a zirconia-based ceramic slurry. The impregnated organic foam is then dried and fired, during which process the organic foam is eliminated. The resulting ceramic foam has roughly the same pore size and density as the organic foam, meaning that these variables can be altered by selecting or designing an organic foam with the desired values. The cooling unit in this instance is physically characterized by a multicellular configuration, with each “cell” having substantially continuous walls and a voided center, but with some degree of porosity to allow impregnation of the volatile species in the liquid phase and outgassing in the vapor phase. In one embodiment, the cooling unit has length and width in accord with the package's lid and thickness of about 1 cm to about 3 cm.

The cooling unit body is impregnated with a cooling medium that is compatible with the reflow equipment, the flip chip package, and the PCB, if applicable. The cooling medium is a solid or liquid substance, such as a volatile liquid species, which has the function of undergoing a reaction or a phase change process to thereby cause heat to be transmitted away from the component. In the invention, “volatile species” refers to any species that has a heat of vaporization below the processing temperature of the stage during which the cooling unit is designed to extract heat from the electronic component. In one embodiment, the volatile species is comprised of the volatile components normally found in a solder flux. One such flux is Alpha NR330, which is available from Alpha Metals of Jersey City, N.J., and which comprises succinic acid, tetraethylene glycol, and dimethyl ether glutaradelhyde. In a second embodiment, the volatile species is water. In a third embodiment, the volatile species is a solution of water and a soluble inorganic or organic species which may undergo an endothermic reaction or process as the water vaporizes and/or may alter the vaporization temperature of the water. Based on the selection of the inorganic or organic species and by varying its concentration, the solution's vaporization temperature can be tailored to meet the specific heat dissipation characteristics the operator desires. By increasing the vaporization temperature of the species, maximum heat dissipation efficiency can be altered to match the process temperature, maximum component temperature, and heat flow characteristics in order to best protect the component. In a preferred embodiment, the soluble inorganic or organic species is selected from the group consisting of mineral salts, ethylene glycol, and any combination thereof. In a fourth embodiment, the volatile species is a solution of a cooling liquid and a soluble inorganic or organic species which may alter the vaporization temperature of the cooling liquid or provide additional endothermic cooling after the cooling liquid vaporizes. In a preferred embodiment, a solution of water and borax (hydrated sodium borate) may be used as the volatile species, wherein the borax provides additional endothermic cooling after the water is vaporized.

The cooling unit body is typically brought into thermal communication by attachment to the component using any acceptable means that is temporary, that will secure the unit to the component during processing operations, and that does not irreparably alter the component's integrity. In one embodiment, the cooling unit body may simply be placed on top of the component's lid, relying on gravity to keep the unit in contact with the component during processing. Other embodiments utilize attachment techniques such as mechanical means, thermal grease, and tacky flux. In FIG. 2, the cooling unit body is shown as being attached by thermal grease or tacky flux, collectively represented as 12.

With reference to FIG. 2, to attach the flip chip package to the PCB, solder spheres 24 are positioned on the surface of the substrate 22. The package is then heat treated to adhere the solder spheres to the package. The package is then dipped in a flux to provide temporary adhesion between the solder spheres and the substrate. Thereafter, the package is oriented on the PCB such that the solder spheres are in contact with electrical contacts on the PCB, which have generally been pretreated with solder paste. The PCB, with at least one flip chip package having a cooling unit attached thereto, is then placed in a reflow oven to reflow the solder spheres. Typical reflow oven dwell time is from about 2 minutes to about 5 minutes, with the particular dwell time dependant on peak processing temperature, the thermal mass of the board and components, their thermal stability, and the type of solder being used. Typical reflow oven temperature is from about 100° C. to about 300° C.

During the elevated temperature process, heat is conducted from the electronic component through the cooling unit body to the cooling medium. The cooling unit body is then cooled by the volatile species' transition from liquid to vapor phase, i.e., vaporization. The endothermic nature of vaporization allows the cooling unit to yield higher cooling efficiency when compared to the cooling characteristics of a traditional reflective heat shield. Specifically, a reflective heat shield only assists in cooling the package by reflecting a portion of the heat directed toward the package and by minimal conduction through the solid material. The efficiency of the reflective heat shield is limited by its reflective properties, which cannot protect the component from infrared heat, and by its surface area, which impacts its conduction properties. In contrast, the cooling unit of the invention dissipates heat by (1) conducting heat away from the package; (2) heating the liquid-phase volatile species to its heat of vaporization; (3) heating the volatile species through the latent heat of vaporization into its vapor phase; and (4) carrying heat from the cooling unit to the oven atmosphere by the outgassing of the vapor-phase volatile species. The general evolution of heat via the cooling unit is represented by the three dashed arrows in FIG. 2.

Advantageously, the cooling unit does not impede the conduction of heat through the PCB during thermal processing. This allows the melting of solder paste, which facilitates attachment of the solder spheres to the PCB, by conduction of heat through the board while maintaining a thermal gradient through the assembly with the highest temperatures at the board-side of the package. More specifically, the thermal gradient produced by utilizing the cooling unit allows solder joint formation or elevated temperature reworking while protecting heat-sensitive features within the package. The thermal gradient is such that the elevated temperature near the soldering or reworking operation at the extremities of the package drops to a safe temperature at the internal features of the package. The specific heat reduction properties of the invention in various processing conditions is further detailed in the Examples below.

As an optional aspect of the invention, the vapor form of the volatile species may be trapped by a recycling management system. The vaporized volatile species may then be allowed to return to their liquid phase and be reused in later cooling units. Such recycling prevents adverse effects on the flip chip package assembly, the PCB, the oven, and the environment, while simultaneously improving the cost efficiency of the system.

In one embodiment, the cooling unit of the invention includes an attached piece of foil. In one embodiment, the foil is placed on the bottom of the cooling unit, between the lid of the package and the cooling unit. In this embodiment, the foil acts to prevent contamination of the package during the endothermic process. In an alternative embodiment, foil is applied to the top of the cooling unit. In this embodiment, the foil facilitates the operation of pick and place operations that utilize vacuum pick-up heads. In yet another embodiment, foil is placed on both the bottom and the top of the cooling unit. Any acceptable attachment mechanism can be used to secure the foil to the cooling unit, such as being cast with the cooling unit in the organic mold or glued in place after the cooling unit has been formed.

In addition to the reflow process, electronic components are exposed to elevated processing temperatures during the preheating stage prior to wave soldering, rework stages, and repair stages. During the preheating stage prior to wave soldering, the electronic component may be exposed to temperatures between about 100° C. to about 200° C. A rework stage is required when a component has undergone normal processing and is potentially viable, but some correctable processing error must be addressed prior to use, e.g., localized solder repair. During rework processing, localized temperatures are elevated to reflow the solder, e.g., between about 100° C. to about 300° C. Similarly, repair processing is required when a discrete part of the electronic component is the root cause of the component's failure. To return the component to operating order, it is typically necessary to heat the localized area including and surrounding the discrete source of failure to elevated temperatures similar to rework levels. In any of these or other elevated temperature processing stages, a cooling unit may be attached to the electronic component to aid in heat dissipation.

In one embodiment, after the processing stage is complete, the cooling unit is removed. In this regard, the invention involves bringing a temporary cooling unit into thermal communication with the electronic component during elevated temperature operations where the temporary cooling unit cools the electronic component and subsequently removing the temporary cooling unit from thermal communication with the electronic component. One particular embodiment involves subjecting the electronic component to elevated temperature operation temperatures between about 125° C. and about 300° C.

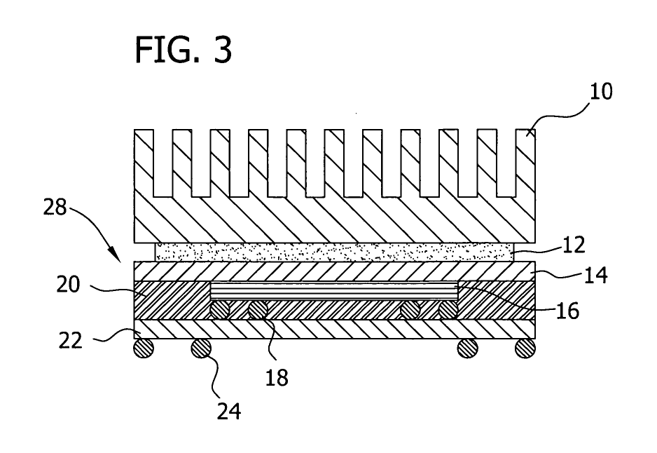

After removal of the cooling unit, an alternate heat dissipation device can be attached to the electronic component, such as a heat sink 10 attached to the lid 14, as seen in FIG. 3. The alternate heat dissipation device may be attached using thermal grease or adhesive, collectively represented as 12. This alternate heat dissipation device will provide permanent, in-service heat dissipation for the package. In other embodiments, the cooling unit remains on the component after processing. In one such embodiment, the cooling unit is a temporary unit in that even though it remains on the component, it serves no further significant cooling or heat-sink function. In another such embodiment, the cooling unit is also serves as a permanent cooling unit in that its configuration is such that it functions as a heat sink during in-service operation even after its cooling medium is exhausted. In this embodiment, the cooling unit can be formed into a shape configuration of a typical heat sink, including cooling fins, as seen in heat sink 10 in FIG. 3.

The following examples further illustrate the invention:

### EXAMPLE 1

125° C. Peak Temperature:

Commercial grade Plaster of Paris (75% CaSO₄) powder was mixed with water in a 2:1 weight ratio. Castings 1 cm thick were formed in an organic tray mold, then cut into six 3 cm×3 cm×1 cm samples using a band saw. The samples were then stored in a desiccator to dry the samples. The samples were weighed at an average weight of 10.75 g. Two samples were soaked in water at room temperature for two hours. Two samples were soaked in NR330 flux (solids content of 4% and pH of 2.6) at room temperature for two hours. The four soaked samples weighed an average of 13.45 g. To compare the affect, if any, of the printed circuit board's thickness, three trials were performed on three boards with a thickness of 60 mils, and three trials were performed on three boards with a thickness of 90 mils. One thermocouple was placed at the center of a semiconductor package on each board (represented by T1), while another thermocouple was placed approximately 1 cm from the edge of the same semiconductor package (represented by T2). The six samples were then exposed to reflow processing at a peak temperature of 125° C. Results:

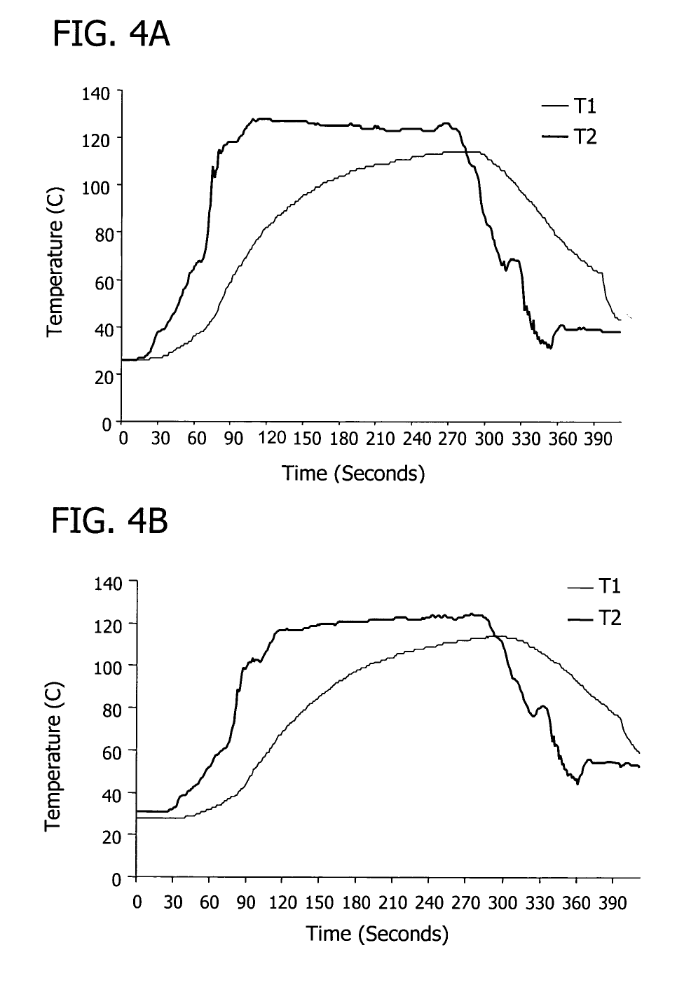

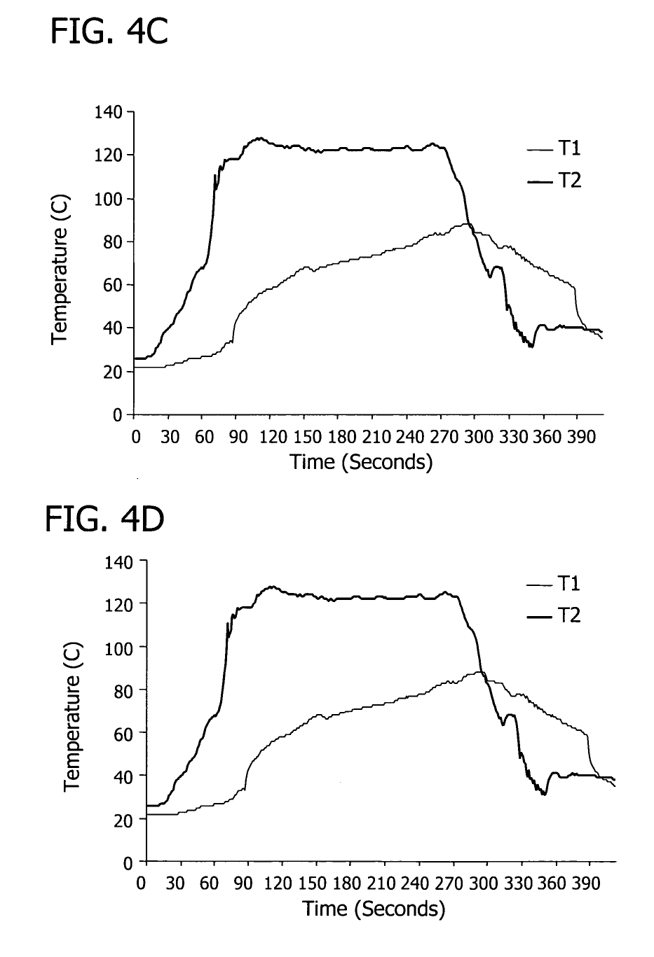

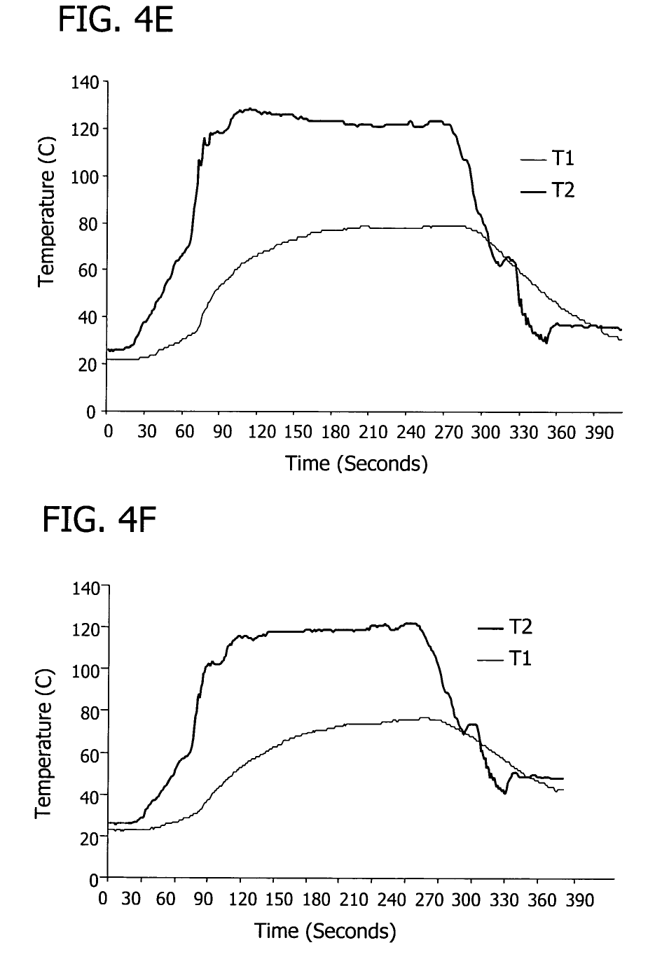

The results of these six trials are illustrated graphically in FIGS. 4a-4f.

Board thickness did not appear to have a consistent effect on the samples' performance.

For the two dry samples, there was virtually no weight loss. The peak temperature at T1 was approximately 9-12° C. lower than at T2.

For the two samples soaked in water, there was a reduction of approximately 10-20% of the absorbed water weight. The peak temperature at T1 was approximately 58-63° C. lower than at T2. Some residue on the boards was evident when the samples were removed after processing.

For the two samples soaked in flux, there was a reduction of approximately 10-20% of the absorbed flux weight. The peak temperature at T1 was approximately 35-45° C. lower than at T2. Some residue on the boards was evident when the samples were removed after processing.

### EXAMPLE 2

220° C. Peak Temperature:

The experimental setup from Example 1 was duplicated to produce six additional samples, two of which were dry, two of which were soaked in water, and two of which were soaked in flux. The experimental procedure was carried out at a peak processing temperature of 220° C. Results:

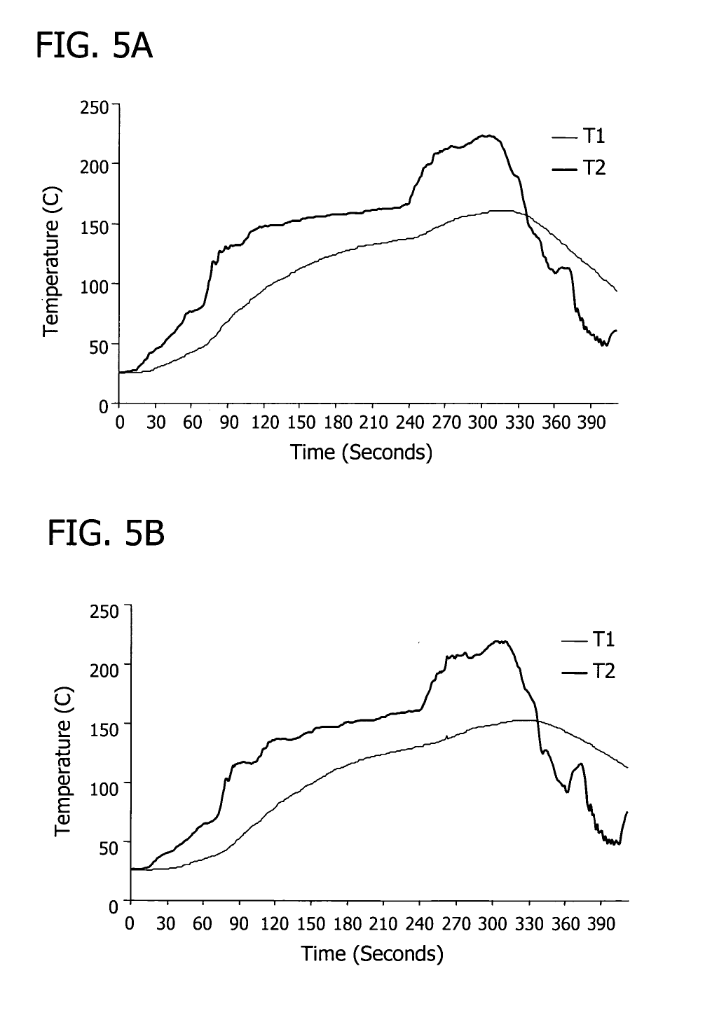

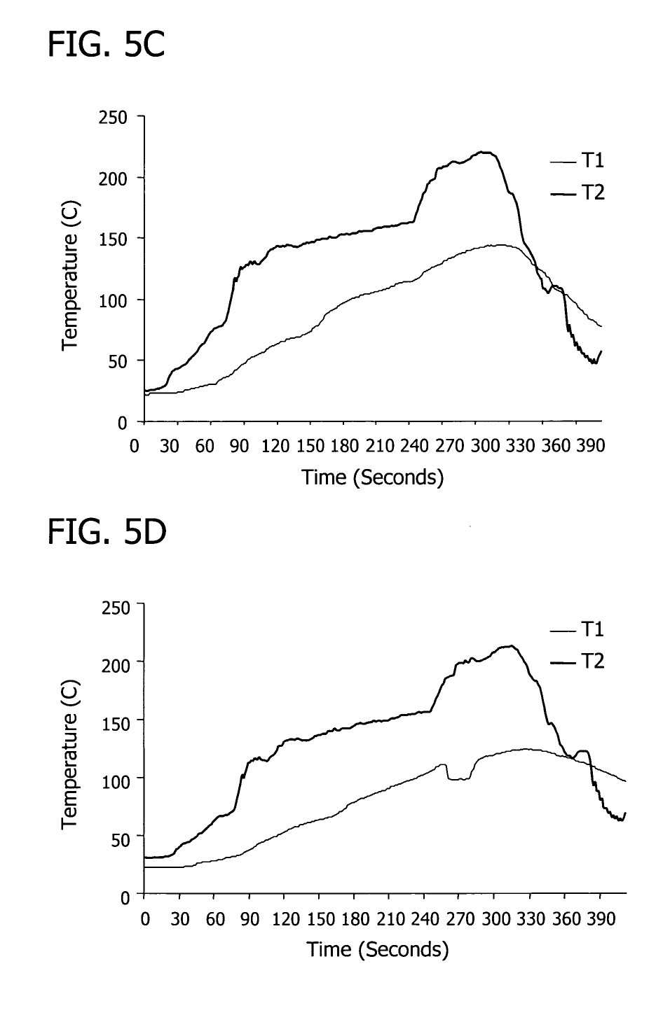

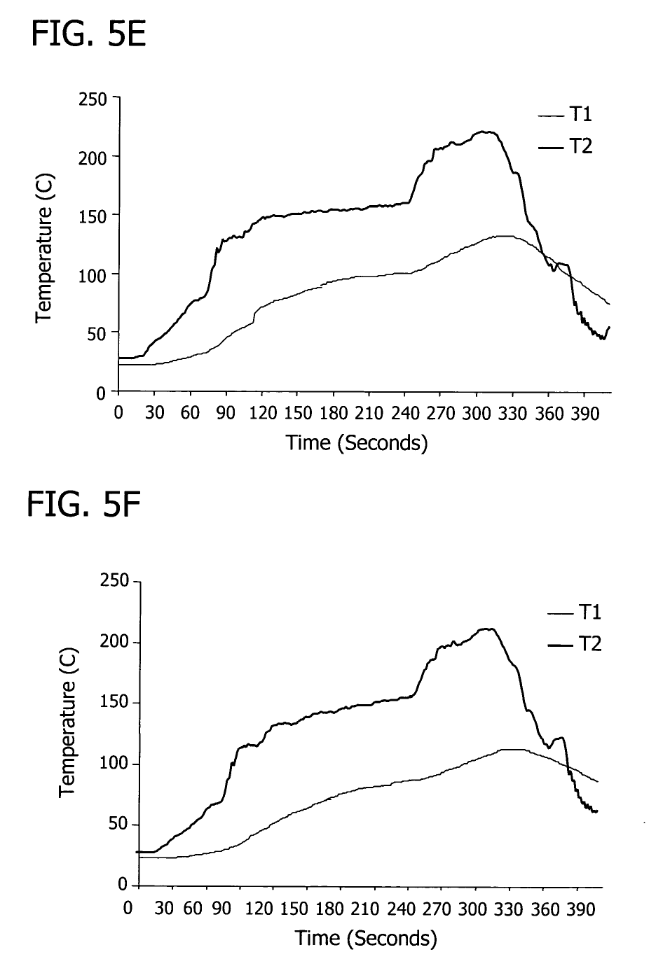

The results of these six trials are illustrated graphically in FIGS. 5a-5f.

Board thickness did not appear to have a consistent effect on the samples' performance.

For the two dry samples, there was a reduction of approximately 7-8% by weight, which represents the residual water of hydration from the original sample mixing process. The peak temperature at T1 was approximately 43-48° C. lower than at T2.

For the two samples soaked in water, there was a reduction of nearly 100% of the absorbed water weight. The peak temperature at T1 was approximately 67-88° C. lower than at T2. Some residue on the boards was evident when the samples were removed after processing.

For the two samples soaked in flux, there was a reduction of approximately 94-97% of the absorbed flux weight. The peak temperature at T1 was approximately 32-70° C. lower than at T2. Some residue on the boards was evident when the samples were removed after processing.

### EXAMPLE 3

260° C. Peak Temperature:

The experimental setup from Example 1 was duplicated to produce six additional samples, two of which were dry, two of which were soaked in water, and two of which were soaked in flux. The experimental procedure was carried out at a peak processing temperature of 260° C.

Results:

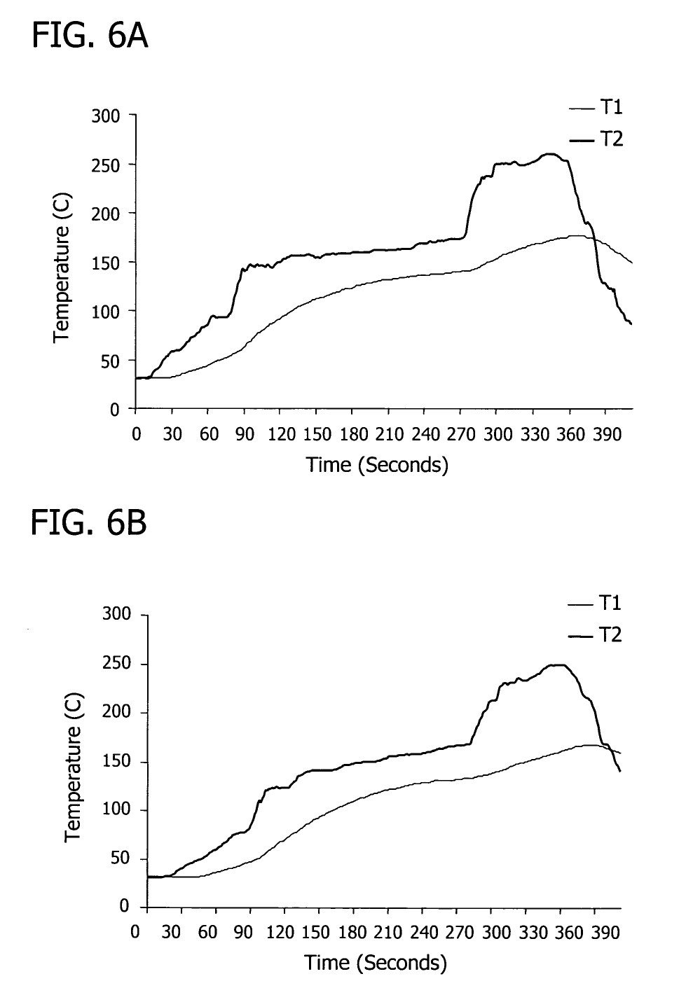

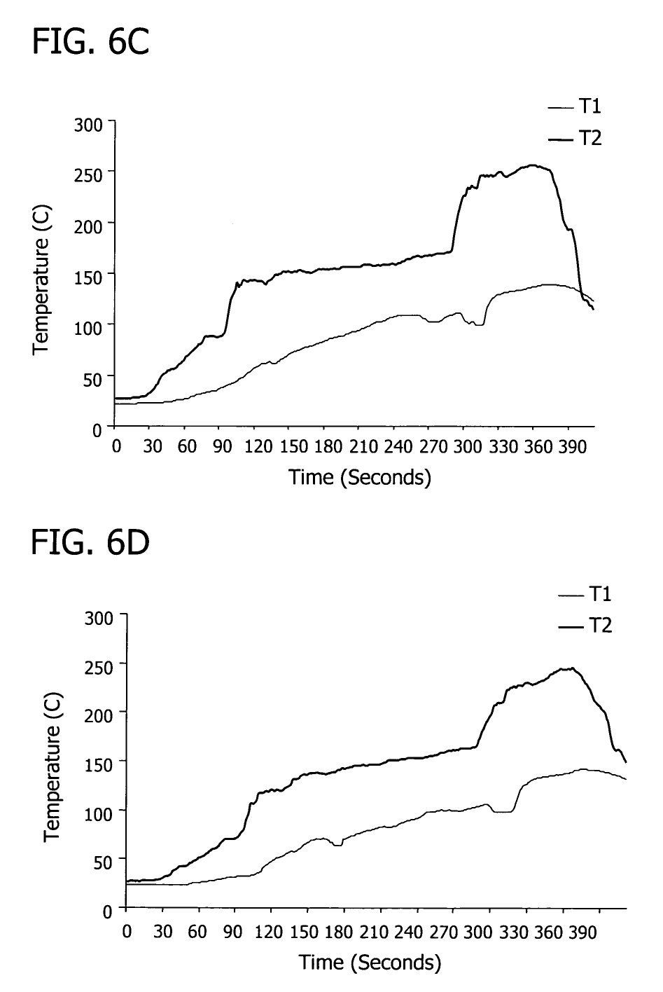

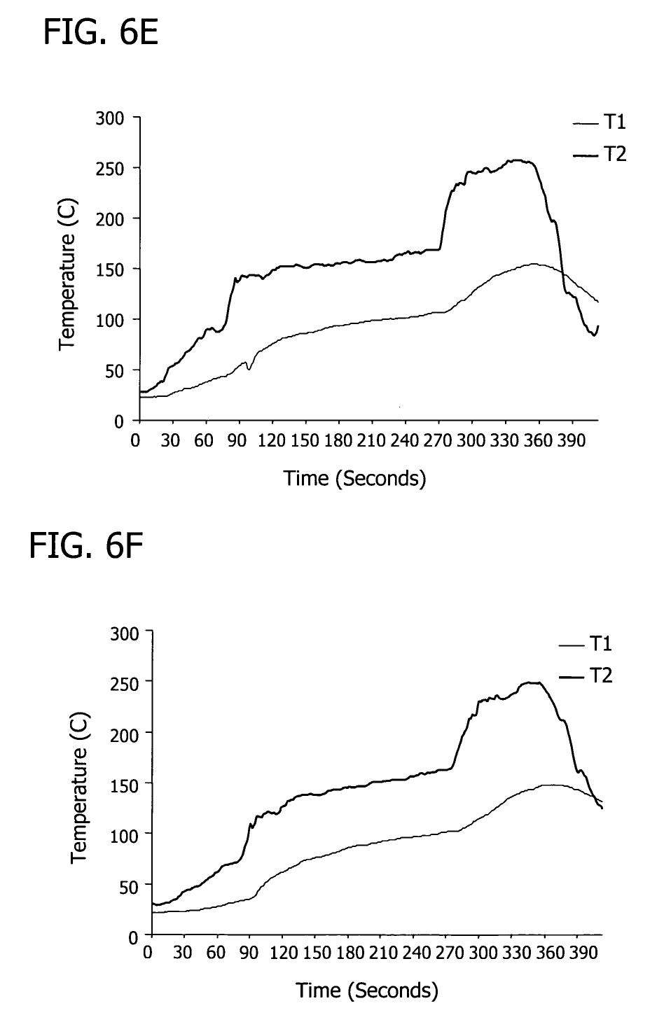

The results of these six trials are illustrated graphically in FIGS. 6a-6f.

Board thickness did not appear to have a consistent effect on the samples' performance.

For the two dry samples, there was a reduction of approximately 8% by weight, which represents the residual water of hydration from the original sample mixing process. The peak temperature at T1 was approximately 47-49° C. lower than at T2.

For the two samples soaked in water, there was a reduction of approximately 100% of the absorbed water weight and approximately 2% of the dry sample's weight, representing a loss of all the water absorbed during the two hour soak plus a portion of the residual water of hydration in the sample. The peak temperature at T1 was approximately 67-68° C. lower than at T2. Some residue on the boards was evident when the samples were removed after processing.

For the two samples soaked in flux, there was a reduction of approximately 100% of the absorbed flux weight and approximately 10% of the dry sample's weight, representing a loss of all the flux absorbed during the two hour soak plus a portion of the residual water of hydration in the sample. The peak temperature at T1 was approximately 73-85° C. lower than at T2. Some residue on the boards was evident when the samples were removed after processing.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above methods and products without departing from the scope of the invention, it is intended that all matter contained in the above description and shown in the accompanying drawings shall be interpreted as illustrative and not in a limiting sense.

What is claimed is:

1. A method for cooling an electronic component during an elevated temperature operation during manufacture, repair, or rework thereof comprising:
bringing a temporary cooling unit into thermal communication with the electronic component;
subjecting the electronic component to said elevated temperature operation during which the temporary cooling unit cools the electronic component; and
removing the temporary cooling unit from thermal communication with the electronic component.

2. The method of claim 1 wherein the temporary cooling unit comprises a cooling unit body and a cooling medium within the cooling unit body.

3. The method of claim 1 wherein subjecting the electronic component to said elevated temperature operation comprises subjecting the electronic component to a process temperature between about 125° C. and about 300° C.;
wherein the temporary cooling unit comprises a cooling medium; and
whereby the cooling medium undergoes a phase change at the process temperature thereby endothermically extracting heat from the electronic component at the process temperature.

4. The method of claim 1 wherein subjecting the electronic component to said elevated temperature operation comprises subjecting the electronic component to a process temperature between about 125° C. and about 300° C.;
wherein the temporary cooling unit comprises a cooling unit body and a cooling liquid within the cooling unit body; and
wherein the cooling liquid has a vaporization temperature between about 100° C. and said process temperature, whereby the 10 cooling liquid undergoes vaporization at the process temperature thereby endothermically extracting heat from the electronic component at the process temperature.

5. The method of claim 1 wherein the temporary cooling unit cools the electronic component by way of an endothermic reaction or process within the cooling unit.

6. The method of claim 1 wherein the temporary cooling unit cools the electronic component by way of an endothermic process selected from among melting, vaporization, and sublimation within the cooling unit.

7. The method of claim 1 wherein the temporary cooling unit comprises an inorganic cooling unit body and a cooling medium within the cooling unit body.

8. The method of claim 7 wherein the inorganic material is selected from the group consisting of hydrated CaSO₄ and reticulated zirconia foam.

9. The method of claim 1 wherein the temporary cooling unit comprises a cooling medium within an inorganic cooling unit body formed by casting ceramic material within a temporary foam mold.

10. The method of claim 1 wherein subjecting the electronic component to said elevated temperature operation comprises subjecting the electronic component to a process temperature between about 125° C. and about 300° C.;
wherein the temporary cooling unit comprises water within a cooling unit body; and
whereby the water undergoes vaporization at the process temperature thereby endothermically extracting heat from the electronic component at the process temperature.

11. The method of claim 1 wherein subjecting the electronic component to said elevated temperature operation comprises subjecting the electronic component to a process temperature between about 125° C. and about 300° C.;
wherein the temporary cooling unit comprises a cooling unit body and a cooling liquid comprising water and soluble inorganic or organic species within the cooling unit body; and
wherein the cooling liquid has a vaporization temperature between about 100° C. and said process temperature, whereby the cooling liquid undergoes vaporization at the process temperature thereby endothermically extracting heat from the electronic component at the process temperature.

12. The method of claim 1 wherein subjecting the electronic component to said elevated temperature operation comprises subjecting the electronic component to a process temperature between about 125° C. and about 300° C.;
wherein the temporary cooling unit comprises a cooling unit body and a cooling liquid comprising a soluble inorganic or organic species within the cooling unit body;
wherein the cooling liquid has a vaporization temperature between about 100° C. and said process temperature, whereby the cooling liquid undergoes vaporization at the process temperature thereby endothermically extracting heat from the electronic component at the process temperature; and
wherein the soluble inorganic or organic species provides additional endothermic cooling after the cooling liquid vaporizes.

13. The method of claim 1 wherein subjecting the electronic component to said elevated temperature operation comprises subjecting the electronic component to a process temperature between about 125° C. and about 300° C.;
wherein the temporary cooling unit comprises a cooling unit body and a cooling medium comprising solder flux material within the cooling unit body; and
wherein the cooling medium has a vaporization temperature between about 100° C. and said process temperature, whereby the cooling medium undergoes vaporization at the process temperature thereby endothermically extracting heat from the electronic component at the process temperature.

14. The method of claim 1 wherein subjecting the electronic component to said elevated temperature operation comprises subjecting the electronic component to a process temperature between about 125° C. and about 300° C.;
wherein the temporary cooling unit comprises a cooling unit body and a cooling liquid within the cooling unit body;
wherein the cooling liquid has a vaporization temperature between about 100° C. and said process temperature, whereby the cooling liquid undergoes vaporization at the process temperature thereby endothermically extracting heat from the electronic component at the process temperature; and
wherein the method further comprises capturing and recycling vapor from vaporization of the cooling liquid.

15. The method of claim 1 wherein bringing the temporary cooling unit into thermal communication with the electronic component comprises attaching the cooling unit to the electronic component by a technique selected from the group comprising gravity, mechanical means, thermal grease, and tacky flux, and any combination thereof.

16. The method of claim 2 wherein the cooling unit further comprises at least one sheet of foil.

17. The method of claim 1 further comprising attaching a permanent heat dissipation device to the electronic component after said removing the temporary cooling unit.

18. A method for cooling an electronic component during an elevated temperature operation during manufacture, repair, or rework thereof comprising:
bringing a cooling unit into thermal communication with the electronic component;
subjecting the electronic component to said elevated temperature operation during which the cooling unit cools the electronic component by way of an endothermic reaction within the cooling unit.

19. The method of claim 18 wherein the cooling unit comprises a cooling unit body and a cooling medium within the cooling unit body.

20. The method of claim 18 wherein subjecting the electronic component to said elevated temperature operation comprises subjecting the electronic component to a process temperature between about 125° C. and about 300° C.;
wherein the cooling unit comprises a cooling unit body and a cooling liquid within the cooling unit body; and
wherein the cooling liquid has a vaporization temperature between about 100° C. and said process temperature, whereby the cooling liquid undergoes vaporization at the process temperature thereby endothermically extracting heat from the electronic component at the process temperature.

21. The method of claim 18 wherein the cooling unit cools the electronic component by way of an endothermic reaction or process within the cooling unit.

22. The method of claim 18 wherein the cooling unit cools the electronic component by way of an endothermic process selected from among melting, vaporization, and sublimation within the cooling unit.

23. The method of claim 18 wherein the cooling unit comprises an inorganic cooling unit body and a cooling medium within the cooling unit body.

24. The method of claim 23 wherein the inorganic material is selected from the group consisting of hydrated CaSO₄ and reticulated zirconia foam.

25. The method of claim 18 wherein the cooling unit comprises a cooling medium within an inorganic cooling unit body formed by casting ceramic material within a temporary foam mold.

26. The method of claim 18 wherein subjecting the electronic component to said elevated temperature operation comprises subjecting the electronic component to a process temperature between about 125° C. and about 300° C.;
wherein the cooling unit comprises water within a cooling unit body; and
whereby the water undergoes vaporization at the process temperature thereby endothermically extracting heat from the electronic component at the process temperature.

27. The method of claim 18 wherein subjecting the electronic component to said elevated temperature operation comprises subjecting the electronic component to a process temperature between about 125° C. and about 300° C.;
wherein the cooling unit comprises a cooling unit body and a cooling liquid comprising water and soluble inorganic or organic species within the cooling unit body; and
wherein the cooling liquid has a vaporization temperature between about 100° C. and said process temperature, whereby the cooling liquid undergoes vaporization at the process temperature thereby endothermically extracting heat from the electronic component at the process temperature.

28. The method of claim 18 wherein subjecting the electronic component to said elevated temperature operation comprises subjecting the electronic component to a process temperature between about 125° C. and about 300° C.;
wherein the cooling unit comprises a cooling unit body and a cooling liquid comprising a soluble inorganic or organic species within the cooling unit body;
wherein the cooling liquid has a vaporization temperature between about 100° C. and said process temperature, whereby the cooling liquid undergoes vaporization at the process temperature thereby endothermically extracting heat from the electronic component at the process temperature; and
wherein the soluble inorganic or organic species provides additional endothermic cooling after the cooling liquid vaporizes.

29. The method of claim 18 wherein subjecting the electronic component to said elevated temperature operation comprises subjecting the electronic component to a process temperature between about 125° C. and about 300° C.;
wherein the cooling unit comprises a cooling unit body and a cooling medium comprising solder flux material within the cooling unit body; and
wherein the cooling medium has a vaporization temperature between about 100° C. and said process temperature, whereby the cooling medium undergoes vaporization at the process temperature thereby endothermically extracting heat from the electronic component at the process temperature.

30. The method of claim 18 wherein subjecting the electronic component to said elevated temperature operation comprises subjecting the electronic component to a process temperature between about 125° C. and about 300° C.;
wherein the cooling unit comprises a cooling unit body and a cooling liquid within the cooling unit body;
wherein the cooling liquid has a vaporization temperature between about 100° C. and said process temperature, whereby the cooling liquid undergoes vaporization at the process temperature thereby endothermically extracting heat from the electronic component at the process temperature; and
wherein the method further comprises capturing and recycling vapor from vaporization of the cooling liquid.

31. The method of claim 18 wherein bringing the cooling unit into thermal communication with the electronic component comprises attaching the cooling unit to the electronic component by a technique selected from the group comprising gravity, mechanical means, thermal grease, and tacky flux, and any combination thereof.

32. The method of claim 18 wherein the cooling unit further comprises at least one sheet of foil.

33. The method of claim 18 further comprising attaching a permanent heat dissipation device to the electronic component after removing the cooling unit.

34. The method of claim 18 wherein the cooling unit comprises a cooling unit body having a heat-sink configuration and a cooling medium within the cooling unit body.

35. The method of claim 18 wherein the cooling unit comprises a cooling unit body and a cooling medium within the cooling unit body, wherein the cooling unit body has a heat-sink configuration for providing cooling during in-service operation of the electronic component.

36. The method of claim 18 wherein the cooling unit comprises a cooling unit body and a cooling medium within the cooling unit body, wherein the cooling unit body has a heat-sink configuration including cooling fins for providing cooling during in-service operation of the electronic component.

37. A cooling unit to extract heat from an electrical component during exposure of the component to a process temperature between 100° C. and 300° C. during manufacture, repair, or reflow of the electrical component, the cooling unit comprising a cooling unit body and a cooling medium within the cooling unit body, wherein the cooling medium undergoes an endothermic process or reaction at said process temperature.

38. The cooling unit of claim 37 wherein the cooling medium within the cooling unit body is a cooling liquid; and
wherein the cooling liquid has a vaporization temperature between about 100° C. and said process temperature, whereby the 5 cooling liquid undergoes vaporization at the process temperature thereby endothermically extracting heat from the electronic component at the process temperature.

39. The cooling unit of claim 37 wherein the cooling unit cools the electronic component by way of an endothermic process selected from among melting, vaporization, and sublimation within the cooling unit.

40. The cooling unit of claim 37 wherein the cooling unit body comprises an inorganic material.

41. The cooling unit of claim 40 wherein the inorganic material is selected from the group consisting of hydrated CaSO₄ and reticulated zirconia foam.

42. The cooling unit of claim 37 wherein the cooling unit comprises a cooling medium within an inorganic cooling unit body formed by casting ceramic material within a temporary foam mold.

43. The cooling unit of claim 37 wherein the cooling medium comprises water within the cooling unit body; and
whereby the water undergoes vaporization at the process temperature thereby endothermically extracting heat from the electronic component at the process temperature.

44. The cooling unit of claim 37 wherein the cooling medium comprises water and soluble inorganic or organic species within the cooling unit body; and
wherein the cooling medium has a vaporization temperature between about 100° C. and said process temperature, whereby the cooling medium undergoes vaporization at the process temperature thereby endothermically extracting heat from the electronic component at the process temperature.

45. The cooling unit of claim 37 wherein the cooling medium comprises a cooling liquid and soluble inorganic or organic species within the cooling unit body; and
wherein the cooling liquid has a vaporization temperature between about 100° C. and said process temperature, whereby the cooling liquid undergoes vaporization at the process temperature thereby endothermically extracting heat from the electronic component at the process temperature; and
wherein the soluble inorganic or organic species provides additional endothermic cooling after the cooling liquid vaporizes.

46. The cooling unit of claim 37 wherein the cooling medium comprises solder flux material within the cooling unit body; and
wherein the cooling medium has a vaporization temperature between about 100° C. and said process temperature, whereby the cooling medium undergoes vaporization at the process temperature thereby endothermically extracting heat from the electronic component at the process temperature.

47. The cooling unit of claim 37 wherein the cooling medium comprises a cooling liquid within the cooling unit body;
wherein the cooling liquid has a vaporization temperature between about 100° C. and said process temperature, whereby the cooling liquid undergoes vaporization at the process temperature thereby endothermically extracting heat from the electronic component at the process temperature; and
wherein the method further comprises capturing and recycling vapor from vaporization of the cooling liquid.

48. The cooling unit of claim 37 wherein the cooling unit further comprises at least one sheet of foil.

49. The cooling unit of claim 37 wherein the cooling unit comprises a cooling unit body having a heat-sink configuration and a cooling medium within the cooling unit body.

50. The cooling unit of claim 37 wherein the cooling unit comprises a cooling unit body and a cooling medium within the cooling unit body, wherein the cooling unit body has a heat-sink configuration for providing cooling during in-service operation of the electronic component.

51. The cooling unit of claim 37 wherein the cooling unit comprises a cooling unit body and a cooling medium within the cooling unit body, wherein the cooling unit body has a heat-sink configuration including cooling fins for providing cooling during in-service operation of the electronic component.
